(19) United States
(12) Patent Application Publication
(10) Pub. No.: US 2002/0113194 A1
(43) Pub. Date: Aug. 22, 2002

(54) Image devices using multiple linear image sensor arrays

(76) Inventors: Darwin Hu, San Jose, CA (US); Alpha Hou, San Jose, CA (US)

Correspondence Address: Joe Zheng, 7394 Wildflower Way, Cupertino, CA, 95014, US

(21) Appl. No.: 09/898,215

(22) Filed: Jul. 2, 2001

Related U.S. Application Data
(63) Continuation-in-part of application No. 09/789,299, filed on Feb. 20, 2001.

(51) Int. Cl. H01L 27/00

(52) U.S. Cl. 250/208.1

(57) ABSTRACT

An image scanning device employing a two-dimensional linear sensor including multiple linear sensors in parallel or arrays of photodetectors is disclosed. The linear sensors in parallel operate in a mode of transfer delay integration to generate charge signals on top of transferred charge signals. The two-dimensional linear sensor produces a scanning signal that is of high fidelity and low noise. As a result, the image scanning device can use low illumination source (e.g. LEDs) and a simple lens. Further, with proper adjustment of the focal length of the lens, a two-dimensional linear sensor of one size may fit all image devices.

### CROSS REFERENCE TO RELATED APPLICATIONS

The present invention is a continuation-in-part of commonly owned U.S. application Ser. No.: 09/789,299, entitled “Motion synchronized two-dimensional linear image sensor array”, filed Feb. 20, 2001, by Alpha Hou, one of the co-inventors hereof.

### BACKGROUND OF THE INVENTION

1. Field of the Invention

The present invention generally relates to color document scanning systems and more particularly relates to image devices employing an image sensor comprising multiple linear arrays or arrays of photodetectors, wherein the arrays are sequentially exposed to a document being scanned to produce scanning signals of high fidelity and strength.

2. Description of the Related Art

There are many applications that need optical scanners to convert paper-based objects, such as texts and graphics, to an electronic format that can be subsequently analyzed, distributed and archived. One of the most popular optical scanners is flatbed scanners that convert scanning objects, including pictures and papers, to images that can be used, for example, for building World Wide Web pages and optical character recognition. Another popular optical scanner is what is called sheet-fed scanners that are small and unobtrusive enough to sit between a keyboard and a computer monitor or integrated into a keyboard or can be carried around to provide a handy scanning means. Most optical scanners are referred to as image scanners as the output thereof is generally in digital image format.

Structurally, an optical scanner generally comprises a photo-sensing module that converts a document image optically into its corresponding electronic signal. Typically, a photo-sensing module comprises an illumination system, an optical system, an image sensor and an output circuit. The illumination system is used to illuminate the document image being scanned. The optical system is used to direct and focus the image light reflected from the document image onto the image sensor. Physically, the image sensor comprises a plurality of photodiodes, photo-transistors (e.g. CMOS or CCD), referred to as photodetectors hereafter, that are sensitive to an incident light and produces an electronic signal, called the pixel or charge signal, from each photodetector. Generally, the pixel signal is proportional to the intensity of the incident light, and the brighter the incident light is, the stronger the pixel signal will be. The output circuit is used to amplify if necessary and convert these pixel signals into an appropriate digital image format for further processing.

The operation of an image sensor comprises two processes, the first being the light integration process and the second being the signal readout process. During the light integration process, each photodetector captures the incident photons of the reflected light from a document that is being imaged or scanned and converts the total number of the incident photons into a proportional amount of an electronic charge or an equivalent pixel signal. At the end of the light integration process, the photodetector is masked so that no further photons would be captured. Next, the photodetector starts the signal readout process during which the pixel signal in the subject photodetector element is read out, via a readout circuit, to a data bus or video bus.

FIG. 1A depicts an internal structure of an exemplary image scanning system 100. Scanning document 101 is illuminated by an illumination source 102. Scanning surface 101 can be moved over or passed through by a moving mechanism a full-width optical lens system 104 that collects reflected light from scanning surface 101 and focuses the reflected light onto an image sensor 106. Various circuits on substrate 108 will read out charge signals from the image sensor and output desired signals. By using the full-width optical lens system 104 and the full-width image sensor 106, the image sensing system 100 allows a full width scanning of scanning document 101. In other words, if scanning document 101 has a width of 8.5 inches, both of optical lens system 104 and image sensor 106 will be at least 8.5 inches or wider. Currently, such optical lens system uses an array of optical rod lens while the image sensor is achieved by concatenating a number of “normal sized” linear sensors.

FIG. 1B illustrates an array of optical rod lens 120 in association with a full-width image sensor 106 of FIG. 1A. Both have to be customized to fit in a scanner for a size. As the width of a scanning document increases, the number of linear sensors (i.e. 106-1, 106-2, . . . and 106-N) increments. If a required width of image sensor 106 is L, then N=[L/n], where the operator [ ] means an integer larger than L/n and n is the size of a normal linear sensor. It is well known in the art that to concatenate a number of linear sensors presents additional problems including alignment of the sensors, non-uniform sensitivity of the sensors, as well as signal processing from each of the sensors. The complication of using a number of linear sensors inherently prevents the costs from going down.

In reality, a scanning document can be different sizes, e.g. ISO A0, A1, A2, A3, A4, A5, A6, B4, B5, B6, C4, C5 and C6, each would require a scanner equipped with an image sensor of appropriate size. The different size requirement makes the design and manufacturing of the image sensor complicated. There is a need for a solution of a generic image sensor that can fit in scanners for different sizes.

### SUMMARY OF THE INVENTION

The present invention has been made in consideration of the demands and associated problems described above and has particular applications to image scanners such as desktop, sheet-fed scanners, facsimile machines or photocopiers. According to one aspect of the present invention, a scanner employing a two-dimensional linear sensor including multiple linear sensors in parallel or arrays of photodetectors. The multiple linear sensors operate in what is referred to as Transfer Delay Integration (TDI). Photodetectors in each of the arrays are serially connected, namely i-th photodetector in each of the arrays is operatively connected in series. When charge signals are generated in one array in response to light reflected from a scanning document, the charge signals are shifted to a next adjacent array. When the scanning document moves across the next adjacent array, the photodetectors generate charge signals on top of the already shifted charge signals. The combined charge signals in the next adjacent array continue to shift to a next array till a last array that produce a scanning signal that is of high fidelity and low noise. As a result, the scanner can use low-cost LED driven light guide and a simple lens in contrast to a bright illumination source and a full-width rod lens array. Further, with proper adjustment of the focal length of the lens, a two-dimensional linear sensor of one size may fit all scanners.

Other objects, together with the foregoing are attained in the exercise of the invention in the following description and resulting in the embodiment illustrated in the accompanying drawings.

### BRIEF DESCRIPTION OF THE DRAWINGS

These and other features, aspects, and advantages of the present invention will become better understood with regard to the following description, appended claims, and accompanying drawings where:

FIG. 1A depicts an internal structure of a typical image scanning system;

FIG. 1B illustrates an array of optical rod lens in association with a full-width image sensor;

FIG. 2 depicts an internal structure of a scanning system using what is called “CIM”, a two-dimensional linear sensor according to one embodiment of the present invention;

FIG. 3 illustrates an exemplary layout of sensor elements with associated image signal processing electronics;

FIG. 4 illustrates an exemplary layout of an image sensor employing multiple arrays of photodetectors according to one embodiment of the present invention;

FIG. 5 shows a local view of the first row of sensor elements from the example layout of the present invention with illustration of charge shifting;

FIG. 6 shows graphically the operations of an image sensor employing four arrays of photodetectors; and

FIG. 7 illustrates the effectiveness of using M arrays of photodetectors.

### DETAILED DESCRIPTION OF THE INVENTION

In the following detailed description of the present invention, numerous specific details are set forth in order to provide a thorough understanding of the present invention. However, it will become obvious to those skilled in the art that the present invention may be practiced without these specific details. In other instances, well known methods, procedures, components, and circuitry have not been described in detail to avoid unnecessarily obscuring aspects of the present invention. The detailed description is presented largely in terms of procedures, logic blocks, processing, and other symbolic representations that directly or indirectly resemble the operations of data processing devices coupled to networks. These process descriptions and representations are the means used by those experienced or skilled in the art to most effectively convey the substance of their work to others skilled in the art.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams representing one or more embodiments of the invention do not inherently indicate any particular order nor imply any limitations in the invention.

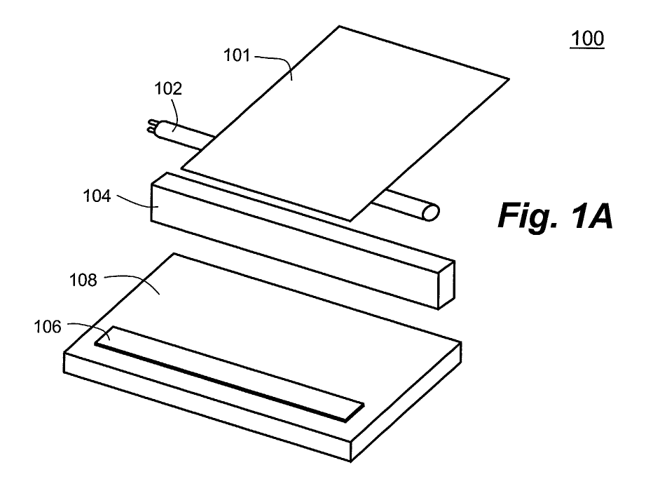

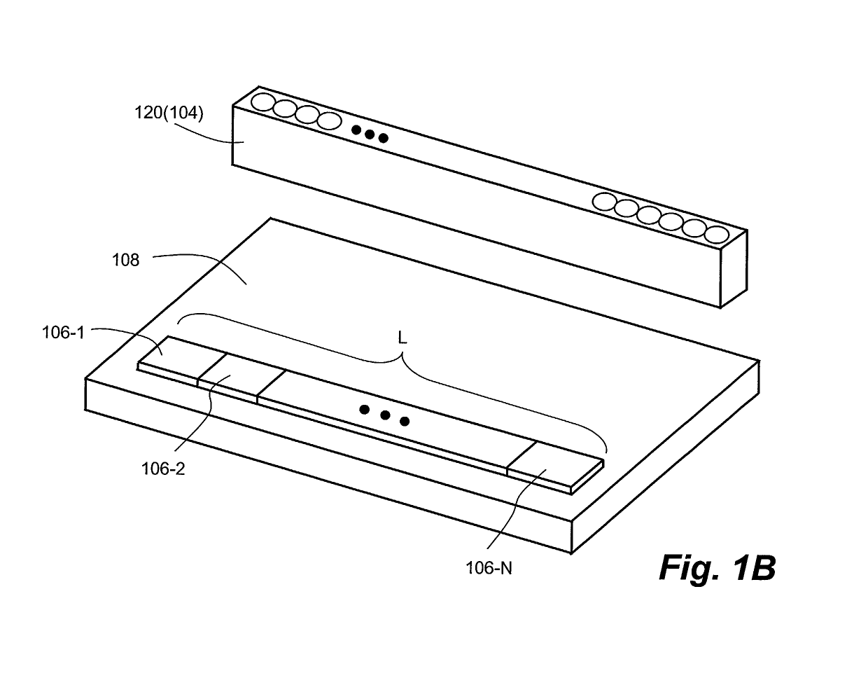

Referring now to the drawings, in which like numerals refer to like parts throughout the drawings. FIG. 2 depicts an internal structure of a scanning system 200. Different from FIG. 1A, scanning system 200 uses a two-dimensional linear sensor 206. Generally a linear sensor is considered a one-dimensional array of photodetectors while a two-dimensional array is that the photodetectors are arranged in an area. As used herein, a two-dimensional linear sensor is an array of linear sensors or multiple arrays of photodetectors, each is exposed to a scanning object at the same time but sequentially exposed to a particular scanning line on the scanning object. In other words, the operation of the multiple arrays of liner sensors therein is synchronized with the movement of the scanning object. According to one embodiment, two-dimensional linear sensor 206 is implemented based on complementary metal oxide semiconductor (CMOS) and hence is referred to as CMOS Image Module or CIM.

Operatively differently from a line sensor in a traditional scanner, two-dimensional linear sensor 206 images a band or multiple lines of document 101 at the same time. As shown in FIG. 2, a band or multiple scanning lines 210 of document 101 are imaged at the same time by two-dimensional linear sensor 206 while the document is advanced line by line. As a result, several lines of the document are imaged at the same and each of the lines is sequentially imaged by each of the linear sensors on two-dimensional linear sensor 206.

The use of two-dimensional linear sensor 206 in a scanner includes one or more of the following advantages and/or benefits. First, the requirement on the illumination strength of illumination source 202 is low because a line of a document is scanned multiple times by the multiple arrays of linear sensors. Now an LED driven light guide can be used in a configuration in which only an optical lens 204 (rather than the full width rod lens array) is used. In the traditional scanners, a cold cathode fluorescent lamp is often used when a single linear sensor is employed, which is often seen in flatbed scanners. The strong illumination from a cold cathode fluorescent lamp ensures that the single linear sensor receives reflected signals strong enough to generate image signals of high signal-to-noise ratio. With the employment of two-dimensional linear sensor 206, the reflected signals do not need to be as strong as required for a single array of photodetectors and the sensor 206 still can produce image signals of high signal-to-noise ratio. Second, because of the use of optical lens 204 that is able to focus an entire scanning line(s) on a document onto a sensor, there is no need to concatenate a number of such two-dimensional linear sensors to accommodate the width of the document. As a result, the problems experienced in the traditional scanners that have to use concatenated linear sensors are vanished. Third, from the design and manufacturing perspective, a two-dimensional linear sensor of one size fits all. In other words, there is now no need to produce two-dimensional linear sensors in different size to accommodate the various widths of documents. Unless it is an image resolution requirement, a simple reduction-lens adjustment with respect to a two-dimensional linear sensor will produce scanners for various scanning requirements. There are other advantages and/or benefits that may be appreciated in the foregoing and following description of the present invention.

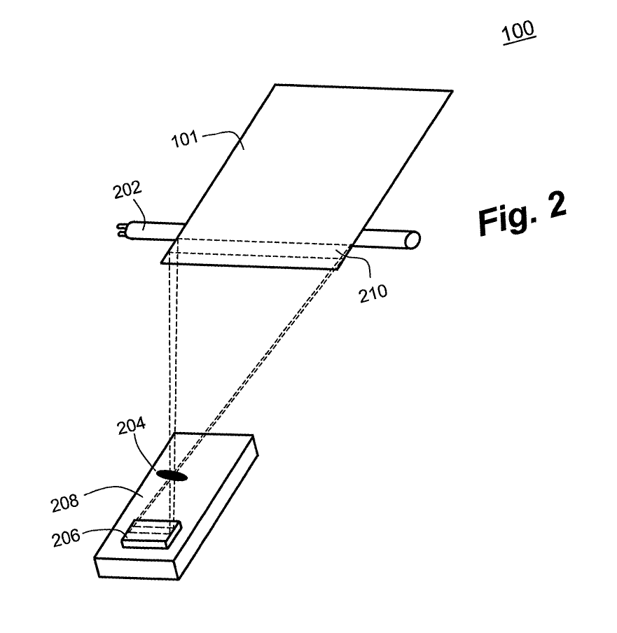

FIG. 3 illustrates a layout of a traditional linear sensor array 302 with associated signal processing electronics 300. Sensor array 302 may correspond to a linear sensor or one of the concatenated linear sensors 106 in FIG. 1A or 1B and comprises a single column of N photodetectors and each is labeled #1, #2, . . . , #N as shown in the figure. During a scanning operation, each of the photodetectors collects image lights cast thereon for an integration period and generates an electronic signal. At the end of the integration period, the electronic signals are amplified in an amplifier array 304 and sampled respectively via a sampling circuit array 306. The amplified and sampled pixel signals are sequentially read out through multiplexers 308 as a final serial image signal output 310, wherein the operation of the multiplexers 308 is controlled by a register array 312. Optionally, the output signals are amplified via an amplifier 314.

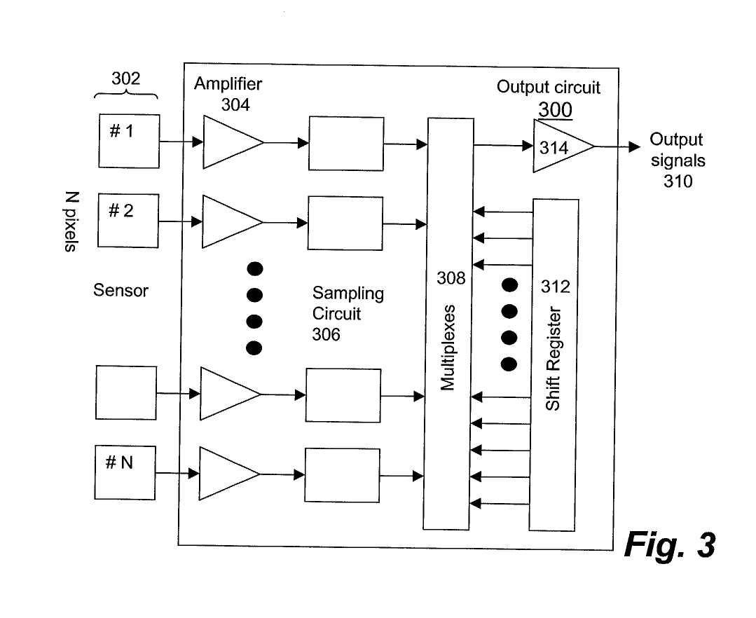

Reference is made to FIG. 4 that illustrates an exemplary sensor layout 400 according to the present invention. Instead of using a single array of photodetectors, the sensor 400 uses multiple arrays of photodetectors or multiple linear sensors. The number (M) of the arrays is greater than 2 and dependent on an exact implementation. For example, M =5, the photodetectors of the first row, are arranged along the direction of document movement and are labeled #1a, #1b, #1c, #1d and #1e, respectively. For the second row, the photodetectors are similarly arranged and are labeled #2a, #2b, #2c, #2d and #2e, etc. Thus, for the N-th row, the photodetectors are labeled #Na, #Nb, #Nc, #Nd and #Ne. That is, as one of the features in the present invention, multiple arrays of photodetectors are used, instead of one array of photodetectors, at each pixel location along the moving direction of a scanning document. These photodetectors will be simultaneously exposed to the reflected image light from the document and their respectively generated photo electronic signals are shifted in series. Each of the shifted signals is added up in a coordinated manner to enhance the quality and fidelity of the captured image for high resolution scanning operation with high scanning throughput.

In operation, along the document moving direction, the center to center distance between adjacent photodetector elements, or equivalently the photodetector pitch, is set to correspond to the scanning resolution. For instance, a 600 DPI scanning resolution means the photodetector pitch is 25.4 mm/600=42.333 micron.

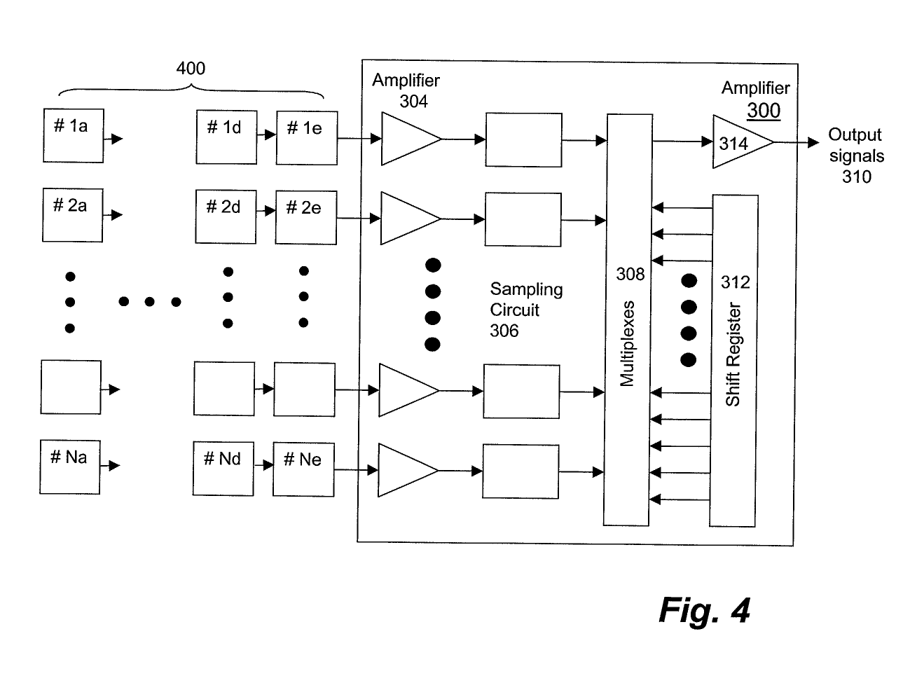

Referring now to FIG. 5, there is shown a pictorial diagram of a row of 4 photodetectors p1, p2, p3 and p4, each of the photodetectors is in a different array of photodetectors. According to one embodiment, an image sensor includes M arrays of photodetectors integrated in parallel, each of the arrays includes N photodetectors, hence i-th photodetector in each of the arrays (e.g. p1, p2, p3 and p4 when M=4) are serially connected, where 0<i<N. In reality, depending on a required scanning resolution, N is in a range of thousands for a document of standard size. To facilitate the operation of the present invention, the M arrays of photodetectors are equally and respectively spaced by a distance D controlled by the scanning resolution.

In FIG. 5, a document 500 is rolling across photodetectors p1, p2, p3 and p4 at a controlled speed. It is assumed that the document is moving from left to right in the figure and hence is exposed to photodetector p4 first. When a scanning line of the document 500 crosses photodetector p4, i.e. at the end of an integration thereof, an electronic signal E4 is generated in photodetector p4 in response to a light reflected from the scanning line (e.g. a scanning spot with respect to one photodetector). When the scanning line of the document 500 is proceeding to photodetector p3, electronic signal E4 is shifted to photodetector p3 first. When the scanning line of the document 500 crosses photodetector p3, an electronic signal E3 is now generated in photodetector p3 in addition to the shifted E4 already stored in photodetector p3. Now the combined E4 and E3 are shifted from photodetector p3 to photodetector p2 before photodetector p2 generates E2 in response to a light reflected from the same scanning line (spot). After the same scanning line (spot) passes photodetector p1, a combined signal E1, E2, E3 and E4 is now available in photodetector p1 and may be amplified in amplifier 502 to yield an accumulated signal 504. It is understood to those skilled in the art that as soon as an electronic signal is shifted from a current photodetector to a next photodetector, the current one is available to generate a new electronic signal to respond to a new incoming scanning spot. Accordingly, the very last photodetector has the accumulated electronic signals from the previous photodetectors. As a result, the signal strength of a scanning signal derived from the accumulated electronic signals is increased in many magnitudes without changing the moving speed of the document. In particular, M=10, the scanning signal could be increased by 10 times. As will be shown below, the signal-to-noise ratio is greatly improved.

According to one embodiment of the present invention, the moving speed of the document is increased by as much as M times. It can be appreciated that the image sensor, by virtue of the present invention, can produce a signal equivalent to from an image sensor using only one array of photodetectors. Depending on an actual implementation, a practical adjustment between the desired scanning speed and the desired signal strength will produce an image scanner with higher scanning throughput and much improved scanning signals.

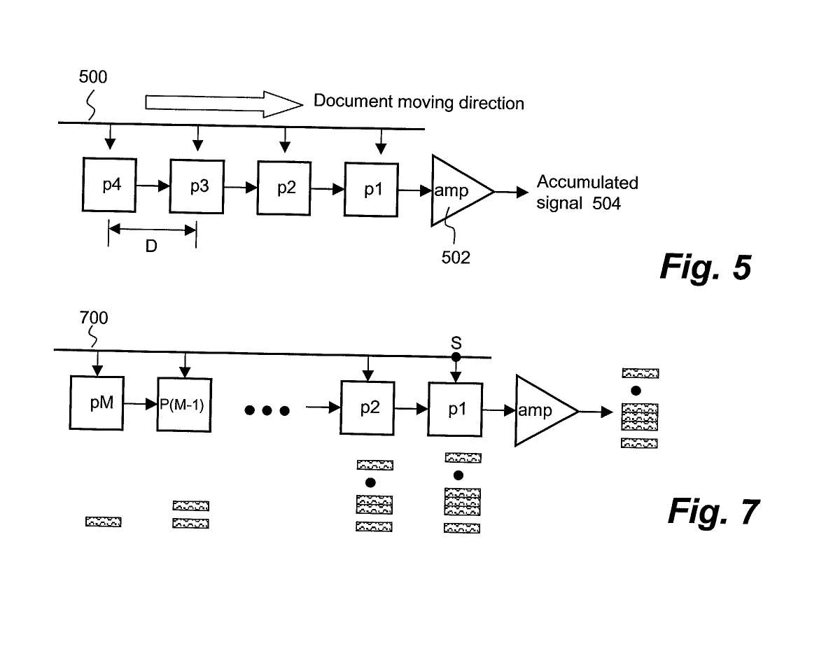

FIG. 6 shows graphically the operations of an image sensor 600 employing four arrays of photodetectors. Photodetectors p1, p2, p3 and p4 are i-th photodetector in each of the arrays. When a scanning document (not shown) is proceeding from left to right or the sensor 600 moves from right to left, photodetectors p4, p3, p2 and p1 are sequentially exposed to the document. Initially, photodetectors p4, p3, p2 and p1 are reset and each stores no electronic signals. After a first relative movement 604 between the image sensor and the document, an electronic signal is generated in each of photodetectors p4, p3, p2 and p1 and designated as E41, E31, E21 and E11 respectively. E41, E31, and E21 are then serially shifted to a next adjacent photodetector while E11 is output through an amplifier. Now the electronic signals are distributed as 610.

After a second relative movement 608 between the image sensor and the document, an electronic signal is generated in each of photodetectors p4, p3, p2 and p1 and designated as E42, E32, E22 and E12 respectively as 612. Again, the charge in each of the photodetectors is shifted to the next adjacent photodetector. The electronic signals are distributed as 614 as a result of the shift and the output is now E21+E12.

After a third relative movement 618 between the image sensor and the document, an electronic signal is generated in each of photodetectors p4, p3, p2 and p1 and designated as E43, E33, E23 and E13 respectively as 620. Once again, the charge in each of the photodetectors is shifted to the next adjacent photodetector. The electronic signals are distributed as 622 as a result of the shift and the output is now E31+E22+E13.

After a fourth relative movement 624 between the image sensor and the document, an electronic signal is generated in each of photodetectors p4, p3, p2 and p1 and designated as E44, E34, E24 and E14 respectively as 626. Once again, the charge in each of the photodetectors is shifted to the next adjacent photodetector. The electronic signals are distributed as 622 as a result of the shift and the output is now E41+E32+E23+E14 which is originally from photodetector p1 before this relative movement 624.

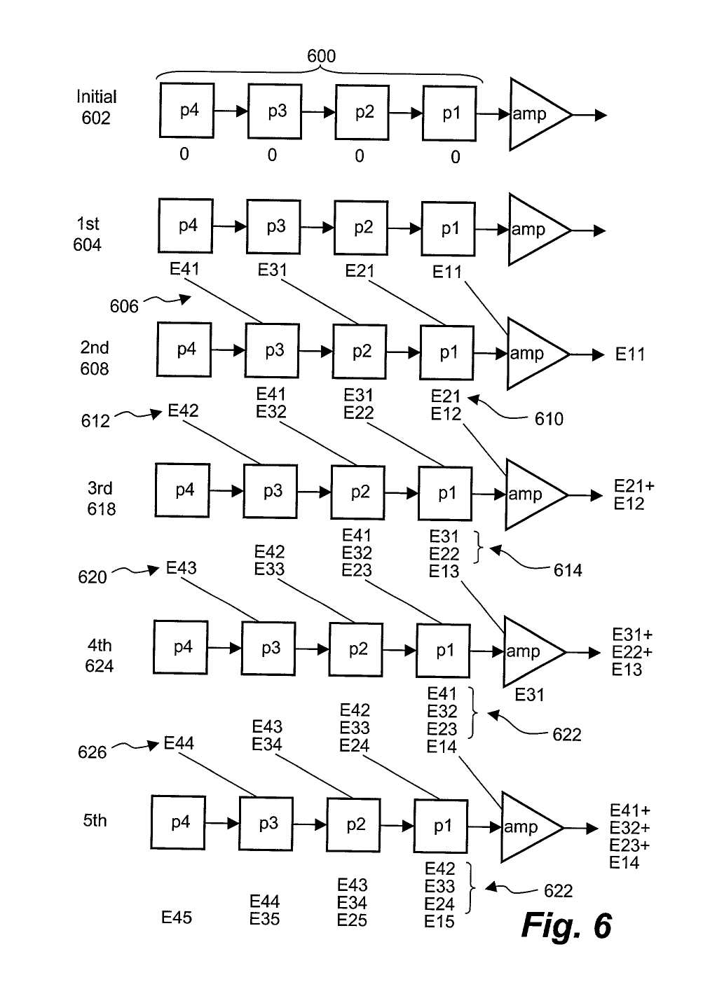

It can be appreciated from the signals shifted as 626, the output of the image sensor 600 is now increased by 4 times since the relative movement between the image sensor and the document is synchronized to ensure that the same scanning spot is sequentially sensed by p4, p3, p2 and p1. FIG. 7 illustrates the effectiveness of using M arrays of photodetectors. As a document 700 moves from left to right, a scanning spot S is exposed to photodetector pM for a light integration process thereof for a short period (e.g. 10 ms) which generates a charge signal. The charge signal is shifted to photodetector p(M−1) before spot S is exposed to photodetector p(M−1) for a light integration process thereof. As shown in the figure, photodetector p(M−1) has already stored the charge signal shifted from photodetector pM, hence photodetector p(M−1) charges from the shifted charged signal and hence results in a new charged signal twice as much as the charge signal in photodetector pM. As the spot S moves past the last photodetector p1, the accumulated charge in p1 produces a scanning signal that has been increased by the number of photodetectors that the spot S has passed.

An important factor affecting the quality of an image scanner is photodetector noise that is an inherent component of the photodetector output. The corresponding figure of merit is called the signal-to-noise ratio, or S/N, in the art. The higher the S/N is, the better the related image quality will be. However, in the context of the present invention employing multiple arrays of photodetector, the final output for a scanning spot from a charge amplifier is equal to the summation of M individual photodetector outputs. Because the photodetector noise from each of the M individual photodetector elements are statistically independent, these noise components tend to be averaged down while the real image pixel signal continues to add up linearly. Therefore, the captured image by a sensor of the present invention will exhibit a higher degree of image quality than that by a sensor of the prior art. The noise reduction in the sensor of the present invention may be further explained as follows:

Assume each of the chare or electronic signal generated in an i-th photodetector in each of M arrays of photodetector is:

S₁, S₂, . . . , S_{M} and the corresponding photodetector noise from the corresponding photodetector element is

N₁, N₂, . . . , N_{M}

In the case of the prior art with a single column of photodetector elements, the signal-to-noise ratio is given by, say

S/N (prior art)=S₁/N₁ (1)

In the case of the present invention, the final output of each pixel signal from the charge amplifier is equal to

Sₜₒₜₐₗ=S₁+S₂+ . . . +S_{M}

As the photodetector noise from the i-th photodetector of each of the arrays is statistically independent, the noise at the final output from the charge amplifier is equal to:

Nₜₒₜₐₗ=(N₁²+N₂²+ . . . +Nₙ²)^{½}

Therefore, in the present invention, the signal-to-noise ratio is given by:

S/N (present invention)=Sₜₒₜₐₗ/Nₜₒₜₐₗ, or

S/N (present invention)=(S₁+S₂+ . . . +Sₙ)/(N₁²+N₂²+ . . . +Nₙ²)^{½} (2)

It is well known that S/N (present invention) is far greater than S/N (prior art), hence a higher quality of image.

The present invention may be implemented as an apparatus, a system or a method, different implementation yields one or more of the following benefits or advantages. One of them is a low cost of an image sensor that provides strong scanning signals with low noise. Another one of them is the ability to provide a higher scanning throughput without requiring the increase of the illumination. Other benefits or advantages can be appreciated in the foregoing description.

The present invention has been described in sufficient detail with a certain degree of particularity. It is understood to those skilled in the art that the present disclosure of embodiments has been made by way of examples only and that numerous changes in the arrangement and combination of parts may be resorted without departing from the spirit and scope of the invention as claimed. While the embodiments discussed herein may appear to include some limitations as to the presentation of the information units, in terms of the format and arrangement, the invention has applicability well beyond such embodiment, which can be appreciated by those skilled in the art. Accordingly, the scope of the present invention is defined by the appended claims rather than the forgoing description of embodiments.

I claim:

1. An image apparatus comprising:
an optical lens;
an illumination source; and
an image sensor including a number of arrays of photodetectors, each of the arrays of photodetectors collecting sequentially reflected light, through the optical lens, from a scanning line of a document being illuminated by the optical lens while the document is moving relatively with respect to the arrays of photodetectors.

2. The image apparatus of claim 1, wherein signals generated in each of the arrays of photodetectors are accumulated to produce a resultant scanning signal from the scanning line of the document.

3. The image apparatus of claim 1, wherein each of the arrays spaced by a distance determined by a scanning resolution.

4. The image apparatus of claim 1, wherein the optical lens is not based on an array of rod lens.

5. The image apparatus of claim 4, wherein the optical lens is made of transparent plastic material.

6. The image apparatus of claim 1, wherein the illumination source employs at least one LED.

7. The image apparatus of claim 6, wherein the illumination source is an LED-driven light wave guide.

8. An image apparatus comprising:
M linear sensors organized in parallel, each of the M linear sensors including N photodetectors, wherein i-th photodetector in each of the M linear sensors is serially connected, and 0<i<N;
wherein an electronic signal is generated in each of the N photodetectors in each of the M linear sensors when a document being scanned moves with respect to the M linear sensors; and
wherein the electronic signal from the i-th photodetector in each of the M linear sensors is accumulated to produce a resultant scanning signal from a scanning line of the document.

9. The image apparatus of claim 8, wherein the electronic signal from the i-th photodetector in one of the M linear sensors is shifted to add into the electronic signal from the i-th photodetector in another one of the M linear sensors when the scanning line passes sequentially the one and the another one of the M linear sensors.

10. The image apparatus of claim 9, wherein a speed at which the document moves with respect to the M linear sensors is determined by a scanning resolution.

11. The image apparatus of claim 10, wherein the M linear sensors are spaced by a distance determined from the scanning resolution.

12. The image apparatus of claim 11, wherein the scanning resolution is determined by a space used to separate the photodetectors in each of the M linear sensors.

13. The image apparatus of claim 11, wherein the scanning resolution is determined by a space used to separate one of the M linear sensors from another one of the M linear sensors.

14. The image apparatus of claim 8, wherein the M linear sensors are packaged on a substrate.

15. The image apparatus of claim 14, wherein the M linear sensors come as a single chip.

16. A method in an image apparatus, the method comprising:
exposing M linear sensors in parallel to a scanning document being imaged, wherein each of the M linear sensors includes N photodetectors, i-th photodetector in each of the M linear sensors is operatively connected, and 0<i<N;
generating an electronic signal from each of the photodetectors in response to reflected light from the scanning document impinged upon the M linear sensors;
shifting the electronic signal from the i-th photodetector in a first one of the M linear sensors to the i-th photodetector in a second one of the M linear sensors after the scanning document passes optically from the first one to the second one of the M linear sensors.

17. The method of claim 16, wherein the M linear sensors are equally spaced by a distance determined from a scanning resolution.

18. The method of claim 17, wherein the scanning resolution is predetermined and controls how fast the document is moved across the M linear sensors.

19. The method of claim 18, wherein the photodetectors in each of the M linear sensors are equally spaced by the distance.

20. The method of claim 16, wherein the M linear sensors are integrated and fabricated on a piece of semiconductor.
